(19) United States
(12) Patent Application Publication
(10) Pub. No.: US 2026/0358368 A1
(43) Pub. Date: Nov. 12, 2026

(54) SOCKET BOARD

(71) Applicant: ADVANTEST CORPORATION, Tokyo (JP)

(72) Inventors: Shigeru MURAYAMA, Tokyo (JP); Takahito SESHIMO, Tokyo (JP)

(21) Appl. No.: 19/263,678

(22) Filed: Jul. 9, 2025

(30) Foreign Application Priority Data
Jul. 12, 2024 (JP) 2024-112797

(51) Int. Cl. G01R 1/04

(52) U.S. Cl. CPC G01R 1/0441

(57) ABSTRACT

A socket board includes a socket printed circuit board and a socket provided on the socket printed circuit board. A nonvolatile memory is provided for each socket printed circuit board and is configured to store information regarding the socket board.

### CROSS REFERENCE TO RELATED APPLICATIONS

The present invention claims priority under 35 U.S.C. § 119 to Japanese Patent Application No. 2024-112797 filed on Jul. 12, 2024, the entire contents of which are incorporated herein by reference.

### BACKGROUND

### 1. Technical Field

The present disclosure relates to a socket board for an automatic test equipment.

### 2. Description of the Related Art

An automatic test equipment (ATE) is used for testing various semiconductor devices such as memory and CPUs (Central Processing Units). The ATE supplies test signals to a semiconductor device under test (hereinafter referred to as DUT), measures the DUT's response to the test signals, determines whether the DUT is acceptable, and identifies defective portions.

In recent years, DRAM (Dynamic Random Access Memory) has been increasing in speed. In GDDR (Graphics Double Data Rate) memory used in graphic boards, the GDDR6X standard achieves a transmission speed of 21 Gbps using the NRZ (Non Return to Zero) method.

In next-generation GDDR7, PAM4 (Pulse Amplitude Modulation 4) is adopted, and the transmission speed is increased up to 40 Gbps. The NRZ method is also advancing in speed year by year, and in the next generation, speeds of approximately 28 Gbps are expected.

Patent Document 1 (Japanese Patent Application Publication No. 2024-014522) discloses an interface device and an automatic test equipment capable of accurately testing high-speed devices. In this interface device, the socket board and the pin electronics circuit are connected via an interposer and wiring.

In automatic test equipment, the management and operation of the socket board are extremely important.

### SUMMARY

The present disclosure has been made in view of such circumstances, and one exemplary object of an aspect thereof is to provide a socket board that can be accurately managed.

A socket board according to one aspect of the present disclosure comprises: a socket printed circuit board; a socket guide provided on the socket printed circuit board; and a non-volatile memory provided on the socket printed circuit board and configured to store information related to the socket board.

It is to be noted that any arbitrary combination or rearrangement of the above-described structural components and so forth is effective as and encompassed by the present embodiments. Moreover, all of the features described in this summary are not necessarily required by embodiments, so that the embodiment may also be a sub-combination of these described features. In addition, embodiments may have other features not described above.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a diagram illustrating an automatic test equipment according to one embodiment;

FIG. 2 is a cross-sectional view of an interface device according to one embodiment;

FIG. 3 is a diagram illustrating a front-end module according to one embodiment;

FIG. 4 is a perspective view showing an example configuration of the FEU in FIG. 3;

FIG. 5 is a cross-sectional view showing an example configuration of the FEU in FIG. 3;

FIG. 6 is a cross-sectional view showing an example of connection between a pin electronics IC and a socket (DUT);

FIG. 7 is a cross-sectional view of a socket board according to the embodiment;

FIG. 8 is a diagram showing a layout of a plurality of second pads on the second surface of the socket PCB;

FIG. 9 is a diagram illustrating a modified example of the layout of a plurality of second pads on the second surface of the socket PCB;

FIG. 10 is a perspective view illustrating the layout of a socket board according to an embodiment;

FIG. 11 is a plan view illustrating the layout of a socket board according to an embodiment;

FIG. 12 is a plan view illustrating the layout of a socket board according to a comparative technique;

FIG. 13 is a plan view illustrating the layout of a socket board according to a modified example; and

FIG. 14 is a diagram illustrating a socket board according to an embodiment.

### DETAILED DESCRIPTION

### Outline of Embodiment

An outline of several example embodiments of the disclosure follows. This outline is provided for the convenience of the reader to provide a basic understanding of such embodiments and does not wholly define the breadth of the disclosure. This outline is not an extensive overview of all contemplated embodiments, and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “one embodiment” may be used herein to refer to a single embodiment or multiple embodiments of the disclosure.

A socket board according to one embodiment comprises: a socket printed circuit board; a socket guide provided on the socket printed circuit board; and a non-volatile memory provided on the socket printed circuit board and configured to store information related to the socket board.

According to this configuration, information can be managed on a per-socket board basis, rather than on a Device Specific Adapter (DSA) basis consisting of multiple socket boards. This makes it possible to conduct test operations while taking into account individual variations between socket boards.

In one embodiment, the non-volatile memory may be disposed along a peripheral edge of the socket printed circuit board. By arranging the socket at the center of the socket printed circuit board and placing the nonvolatile memory along the periphery, the impact on the wiring layout of signal lines and ground lines for the DUT can be minimized.

In one embodiment, the non-volatile memory may be disposed at one of four corners of the socket printed circuit board.

Automatic test equipment according to one embodiment includes the socket board described above.

### Embodiments

Preferred embodiments will be described below with reference to the drawings. The same or equivalent components, members, and processes shown in the drawings are assigned the same reference numerals, and redundant descriptions will be omitted as appropriate. The embodiments are illustrative and are not intended to limit the disclosure or the invention, and not all features and combinations described in the embodiments are necessarily essential to the disclosure or the invention.

The dimensions (such as thickness, length, and width) of the respective components shown in the drawings may be enlarged or reduced as appropriate for ease of understanding. Furthermore, the dimensions of multiple components do not necessarily reflect their relative size relationship, and it is possible that a member A, although drawn thicker than another member B in the drawings, is in fact thinner than member B.

In the present specification, the expression “a state in which member A is connected to member B” includes not only the case where member A and member B are physically and directly connected, but also the case where they are indirectly connected via other members, as long as such connection does not substantially affect their electrical connection state or impair the function or effect achieved by their combination.

Similarly, the expression “a state in which member C is connected (or provided) between member A and member B” includes not only the case where member A and member C or member B and member C are directly connected, but also the case where they are indirectly connected via other members, as long as such connection does not substantially affect their electrical connection state or impair the function or effect achieved by their combination.

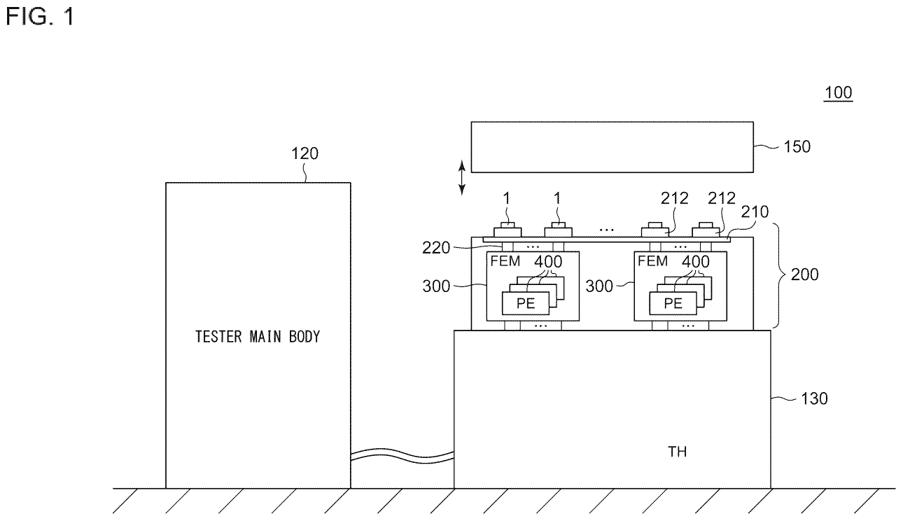

FIG. 1 is a diagram illustrating an automatic test equipment 100 according to the embodiment. The automatic test equipment 100 includes a tester 120, a test head 130, a handler 150, and an interface device 200.

The tester 120 performs overall control of the automatic test equipment 100. Specifically, the tester 120 executes a test program, controls the test head 130 and the handler 150, and collects measurement results.

The handler 150 loads the DUT 1 into the interface device 200 and unloads the tested DUT 1 from the interface device 200. The handler 150 also sorts the DUT 1 into acceptable and defective devices.

The test head 130 includes hardware that generates test signals to be supplied to the DUT 1 and detects signals from the DUT (referred to as device signals). It may also include a power supply circuit that generates supply voltages to be provided to the DUT 1 and the interface device 200.

The interface device 200 includes a socket board 210, wiring 220, and a front-end module 300.

In the present embodiment, a plurality of pin electronics ICs (PE-ICs) 400 are provided not within the test head 130 but in the interface device 200. The pin electronics IC 400 is an application-specific integrated circuit (ASIC) in which a driver that generates test signals and a comparator that receives device signals are integrated. The test signals and device signals may be implemented as NRZ signals or PAM4 signals.

More specifically, the plurality of pin electronics ICs 400 are modularized. This module is referred to as the front-end module 300.

A plurality of sockets 212 are provided on the socket board 210. The DUT 1 is mounted in the socket 212. The front-end module 300 and the socket 212 are connected via wiring 220.

The above describes the configuration of the automatic test equipment 100.

According to the automatic test equipment 100, by incorporating the front-end module 300, in which the plurality of pin electronics ICs 400 are modularized, into the interface device 200, the pin electronics ICs 400 can be placed in close proximity to the DUT 1. As a result, the transmission distance of the test signals and the device signals can be significantly shortened compared to conventional configurations.

For example, in a conventional automatic test equipment, the pin electronics IC and the socket board are connected by a coaxial cable having a length of about 500 mm to 600 mm. In contrast, in the present embodiment, the length of the wiring 220 can be shortened to about 100 mm to 150 mm. This significantly reduces the loss of high-frequency components and enables transmission of high-speed test and device signals. The automatic test equipment 100 including the interface device 200 can test high-speed memory operating at more than 20 Gbps.

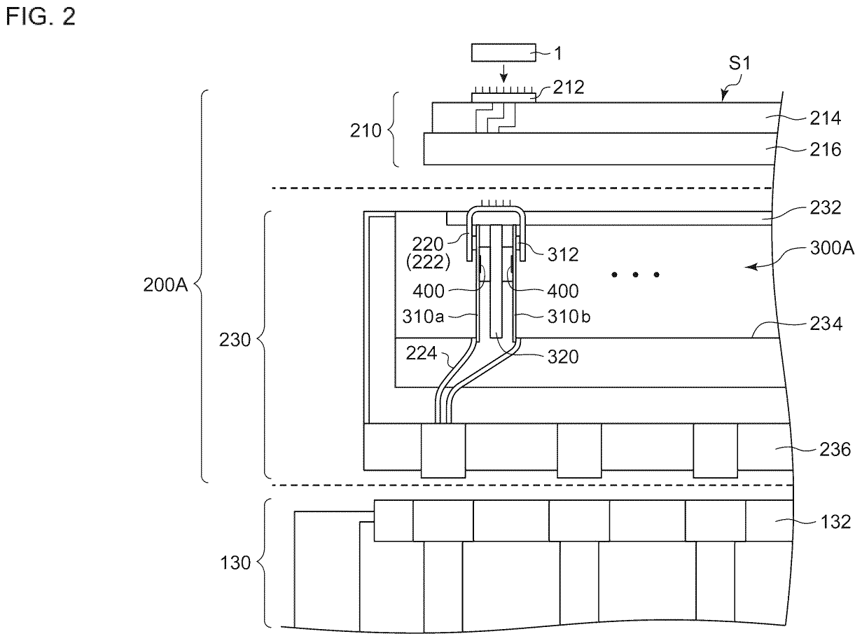

FIG. 2 is a cross-sectional view of an interface device 200A according to one embodiment. FIG. 2 shows only the configuration related to one DUT. In this embodiment, the interface device 200A includes a motherboard 230 and a socket board 210 that is removably connected to the motherboard 230. The socket board 210 includes a socket 212 (also referred to as a socket guide) as a mechanical component, a socket printed circuit board (socket PCB) 214, and a socket-board-side connector 216. In the present specification, the socket PCB itself is referred to as the “socket board,” and the entire socket PCB on which the socket guide is mounted is referred to as the “DSA” (Device Specific Adapter) or “Device Board”.

The front-end module 300A includes a plurality of printed circuit boards (pin electronics PCBs) 310 on which a plurality of pin electronics ICs 400 are mounted. The pin electronics PCBs 310 are arranged perpendicular to the surface of the DUT (front and back sides), in other words, perpendicular to the surface S1 of the socket board 210. In the present embodiment, the socket board 210 is horizontal with respect to the ground, and therefore the pin electronics PCBs 310 are arranged parallel to the direction of gravity.

The front-end module 300A further includes a plate-shaped cooling device (hereinafter referred to as a cold plate) 320. The cold plate 320 has a flow path through which a coolant circulates.

The pin electronics PCBs 310a and 310b and the cold plate 320 are laminated in such a manner that the pin electronics ICs 400 are thermally coupled to the cold plate 320.

The motherboard 230 includes a socket-board-side connector 232, a spacing frame 234, and a relay connector 236. The front-end module 300A is fixed to the spacing frame 234. The relay connector 236 is electrically and mechanically connected to a test-head-side connector 132.

As will be described in detail later, the wiring 220 may use a cable made of a flexible printed circuit (FPC), also referred to as an FPC cable, instead of a conventional coaxial cable.

On the other hand, in the wiring 224 between the pin electronics PCB 310 and the relay connector 236, only control signals to the pin electronics ICs 400 are transmitted, and test signals and device signals are not transmitted. Therefore, the wiring 224 may use coaxial cables.

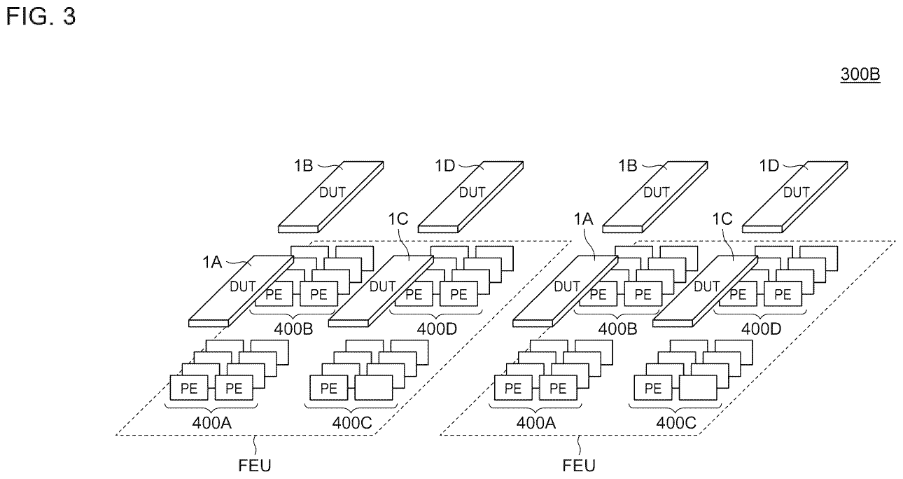

FIG. 3 illustrates a front-end module 300B according to one embodiment.

For each DUT 1, 2×M (M≥1 ) pin electronics ICs 400 are assigned. The multiple DUTs and pin electronics ICs 400 are distinguished as necessary by appending subscripts A through D. In this example, assuming that DUT1 has 192 input/output terminals (I/Os), and that each pin electronics IC 400 has 24 I/Os, 192/24=8 pin electronics ICs 400 (i.e., M=4) are assigned per DUT.

The front-end module 300B is divided and configured per N (N≥2) DUTs, and each division unit is referred to as a front-end unit (FEU). In this example, each FEU comprises a block corresponding to four DUTs, and each FEU includes 2×M×N=2×4×4=32 pin electronics ICs 400.

FIG. 3 shows two FEUs, but in practice, the front-end module 300B may include two or more FEUs. For example, in an ATE capable of measuring 64 DUTs simultaneously, 64/4=16 FEUs are provided, and the entire front-end module 300B is equipped with 64×192 I/Os=12,288 I/Os.

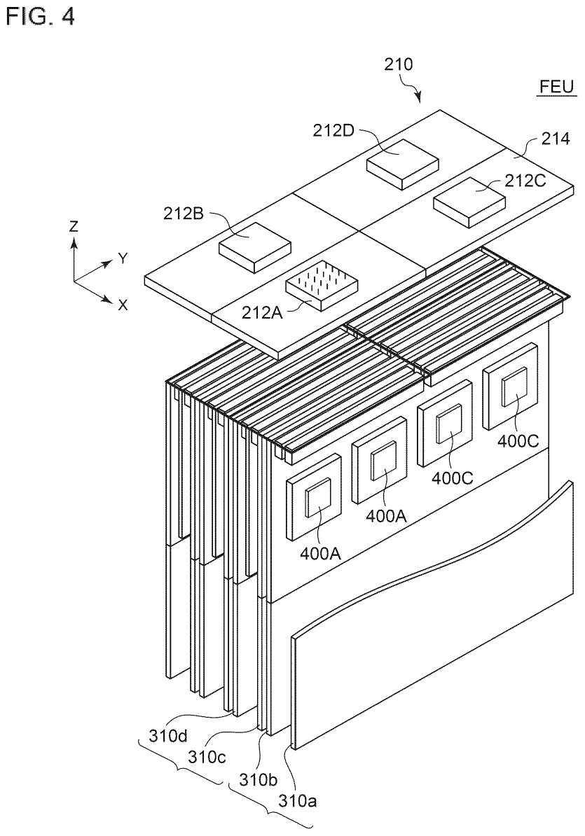

FIG. 4 is a perspective view illustrating an example configuration of the FEU in FIG. 3. The sockets 212A to 212D corresponding to the four DUTs are arranged in a two-row, two-column matrix. Focusing on one DUT 1A, the eight pin electronics ICs 400A assigned to it are mounted in pairs on four pin electronics PCBs 310a to 310d arranged in the X direction. The socket PCB 214 on which the sockets 212 are mounted may be divided per DUT, or a single socket PCB 214 corresponding to four DUTs may be configured as an integrated board.

The two pin electronics ICs 400A mounted on a single pin electronics PCB 310 are arranged in the Y direction. The two pin electronics ICs 400A are positioned equidistant from the DUT 1A.

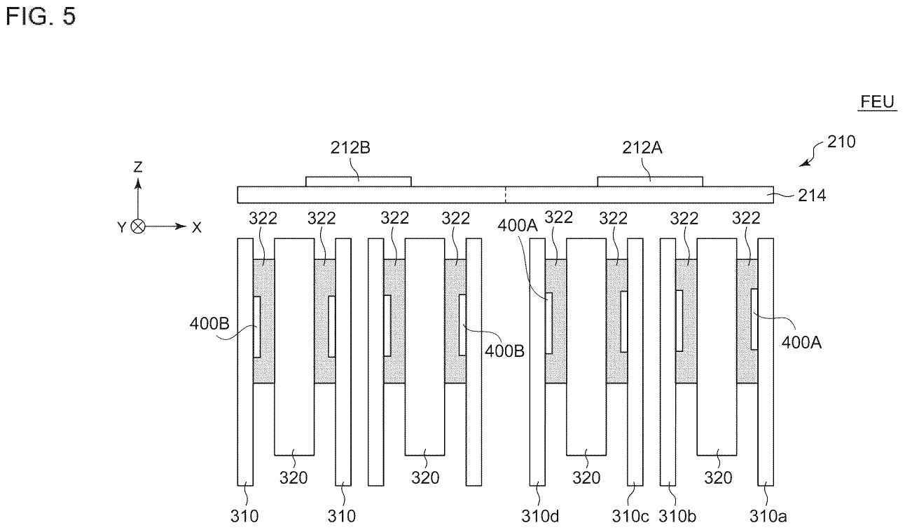

FIG. 5 is a cross-sectional view illustrating an example configuration of the FEU in FIG. 3. As shown in FIG. 2, a cold plate 320 is provided between the two pin electronics PCBs 310a and 310b. Similarly, another cold plate 320 is also provided between the two pin electronics PCBs 310c and 310d. As described above, the pin electronics ICs 400 are mounted on locations on the pin electronics PCBs 310 close to the socket board 210. In order to improve cooling efficiency, the pin electronics ICs 400 may be implemented as bare chips, and the pin electronics ICs 400 are thermally coupled to the cold plate 320 via a thermal interface material (TIM) 322.

When the FEU is viewed in plan from above along the Y-axis direction, the DUT center —namely the socket 212A—is located at the center of four (M) pin electronics PCBs 310a to 310d, which are stacked along the X direction.

The above describes the configuration of the FEU.

The advantages of this FEU will now be described. Focusing on the DUT 1A, designated with the subscript A, by mounting the plurality of pin electronics ICs 400A (eight in this example) corresponding to one DUT 1A in pairs on each of the four pin electronics PCBs 310a to 310d, the distance from each of the eight pin electronics ICs 400A to the socket 212A can be made uniform. As a result, the loss of the transmission lines from each pin electronics IC 400A to the socket 212A (i.e., DUT 1A) can be made uniform, enabling accurate testing.

Next, the electrical connection between the pin electronics ICs 400 and the socket 212 will be described.

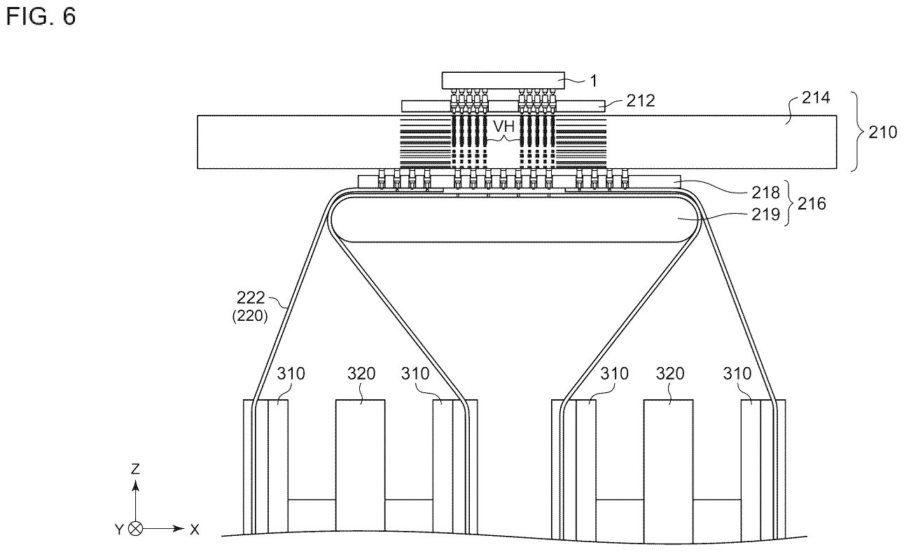

FIG. 6 is a cross-sectional view illustrating an example of the connection between the pin electronics IC and the socket (DUT 1). The transmission line through which the test signals and device signals propagate, namely the wiring 220 between the pin electronics PCB 310 and the socket board 210, uses an FPC cable 222.

When coaxial cables are used as the wiring 220 between the pin electronics PCB 310 and the socket board 210, the minimum distance between the pin electronics PCB 310 and the socket board 210 is restricted due to the rigidity of the coaxial cables. In contrast, by using the FPC cable 222, its flexibility allows the distance h between the pin electronics PCB 310 and the socket board 210 to be reduced compared to the case where coaxial cables are used, thereby shortening the transmission distance for the test signals and device signals.

In conventional test systems, when making the socket board 210 detachable, it is common to use a Low Insertion Force (LIF) connector. However, such LIF connectors exhibit a significant loss of approximately −3 dB in frequency bands above 14 GHz and may cause waveform distortion during high-speed transmission at 28 Gbps or 40 Gbps. By using an FPC cable 222 for the wiring 220, the LIF connector becomes unnecessary, thereby suppressing waveform distortion caused by high-frequency attenuation and enabling accurate testing.

More specifically, the socket board 210 includes a socket 212 and a socket PCB 214. The socket PCB 214 is a multilayer board comprising wiring layers and insulating layers. The wiring layers include traces for transmitting signals in the horizontal direction, while the insulating layers include via holes VH for transmitting signals in the vertical direction. It is preferable that the paths through which test signals and device signals are transmitted be drawn out to the rear surface of the socket board 210 without substantial horizontal (X and Y direction) routing. On the other hand, for power signals and control signals of lower frequency, routing in the horizontal direction within the socket PCB 214 is permissible.

The FPC cable 222 and the socket board 210 are connected by a socket board-side connector 216. The socket board-side connector 216 includes an interposer 218 and a cable clamp 219.

The interposer 218 and the socket PCB 214 are structured to be detachable. Electrodes exposed on the surface of the interposer 218 are electrically connected to electrodes exposed on the rear surface of the socket PCB 214. The FPC cable 222 is clamped by the cable clamp 219 in a state of being in contact with the rear surface electrodes of the interposer 218.

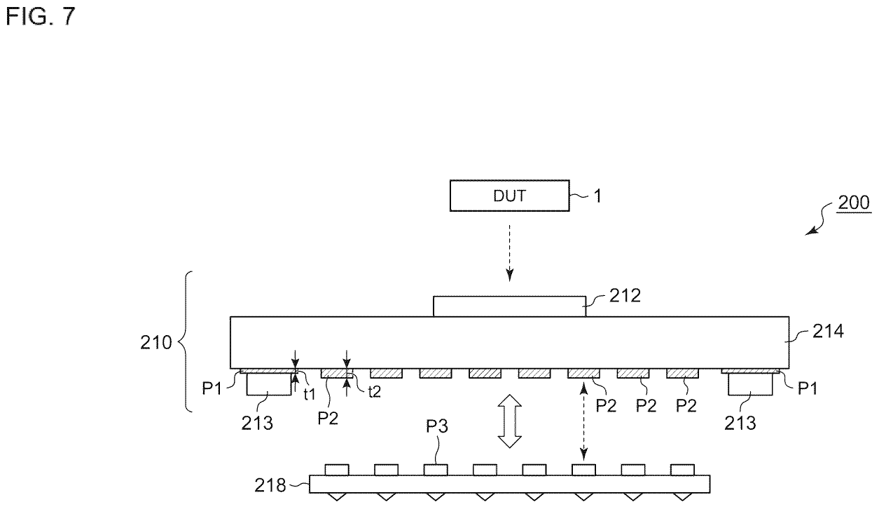

FIG. 7 is a cross-sectional view of the socket board 210 according to the embodiment. On the first surface of the socket PCB 214 of the socket board 210, the socket 212 is provided and connected to the DUT. The second surface of the socket board 210 is structured to be detachably connected to the interposer 218.

On the second surface side of the socket board 210, surface mount devices (SMDs) 213 are mounted. Examples of the SMDs 213 include chip capacitors, chip resistors, and chip inductors. On the second surface of the socket PCB 214, a plurality of first pads (lands) P1 for mounting the SMDs 213 are formed.

In addition, on the second surface of the socket PCB 214, a plurality of second pads P2 that serve as electrical contacts with the interposer 218 are formed. The second pads P2 are electrically connected to corresponding contacts (pins) P3 of the interposer 218.

The first pads P1 have a thickness t1, and the second pads P2 have a thickness t2, where the thicknesses t1 and t2 of the two types of pads P1 and P2 differ from each other (t1≠t2). Specifically, the relationship t2>t1 holds.

Preferably, the thickness t2 of the second pads P2 is at least twice the thickness t1 of the first pads P1. More preferably, the thickness t2 of the second pads P2 is at least five times the thickness t1 of the first pads P1. Still more preferably, the thickness t2 of the second pads P2 is at least eight times the thickness t1 of the first pads P1.

For example, the thickness t1 of the first pads P1 is 0.03 microns, with a dimensional tolerance of ±30%. In contrast, the thickness t2 of the second pads P2 is 0.5 microns, also with a dimensional tolerance of ±30%. In this case, the thickness t2 of the second pads P2 is sixteen times the thickness t1 of the first pads P1.

According to this socket board 210, by providing different thicknesses for the first pads P1 for mounting components and the second pads P2 serving as electrical contacts with the interposer 218, the peel strength of the SMDs 213 can be increased, while the wear resistance of the electrical contacts with the interposer 218 can be improved, thereby enhancing long-term reliability.

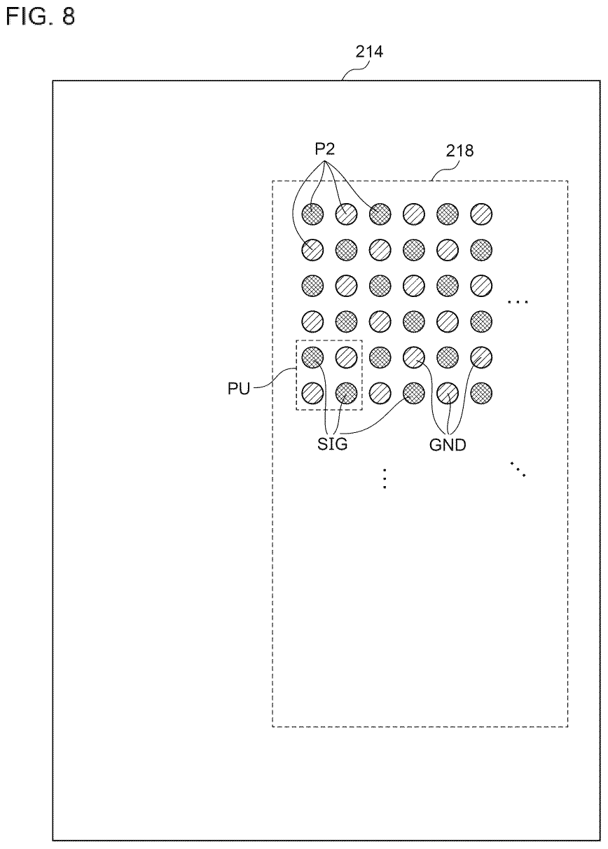

FIG. 8 is a diagram illustrating a layout of the plurality of second pads P2 on the second surface of the socket PCB 214. A plurality of pins (P3 in FIG. 8) arranged in a matrix are provided on the surface of the interposer 218, and a corresponding plurality of second pads P2 are arranged in a matrix on the second surface of the socket PCB 214.

In both the row direction (vertical on the page) and the column direction (horizontal on the page), the plurality of second pads P2 are alternately assigned to signal pins SIG and ground pins GND. In other words, each signal pin SIG is assigned such that ground pins GND are adjacent in the row and column directions, and signal pins SIG are adjacent in the diagonal directions. Alternatively, the arrangement can be understood as consisting of a minimum unit PU of a 2-row by 2-column block, in which two signal pins SIG and two ground pins GND are arranged diagonally. This minimum unit PU is repeatedly arranged in the row and column directions.

The foregoing describes the layout of the second pads P2 on the socket PCB 214. This layout enables a higher signal pin density and a reduction in the area of the socket printed circuit board compared to a layout in which each signal pin is completely surrounded by ground pins in the row, column, and diagonal directions.

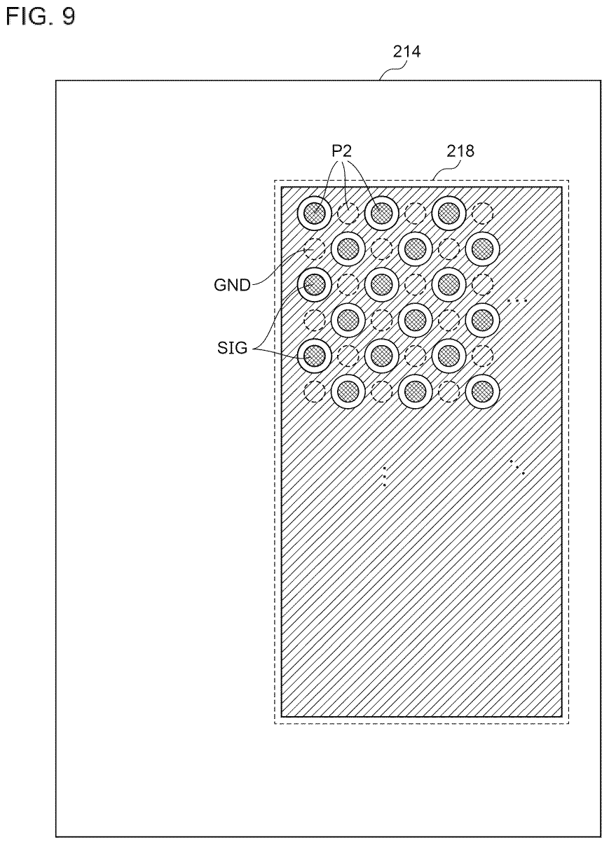

FIG. 9 illustrates a variation of the layout of the plurality of second pads P2 on the second surface of the socket PCB 214. In this variation, among the plurality of second pads P2, the ground pins GND are formed continuously.

According to this variation, the impedance of the ground pins GND can be reduced.

Subsequently, the layout of DUTs and signals on the socket board will be described.

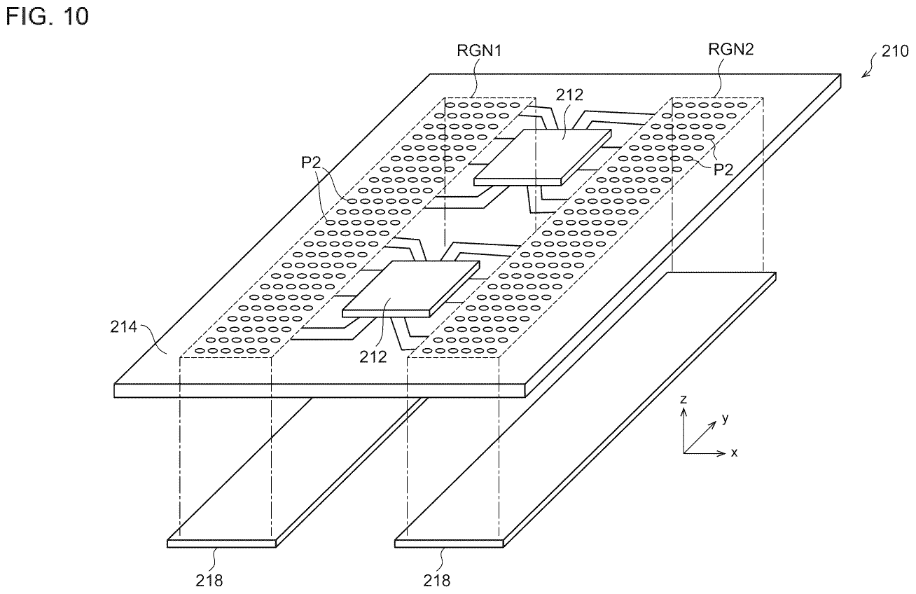

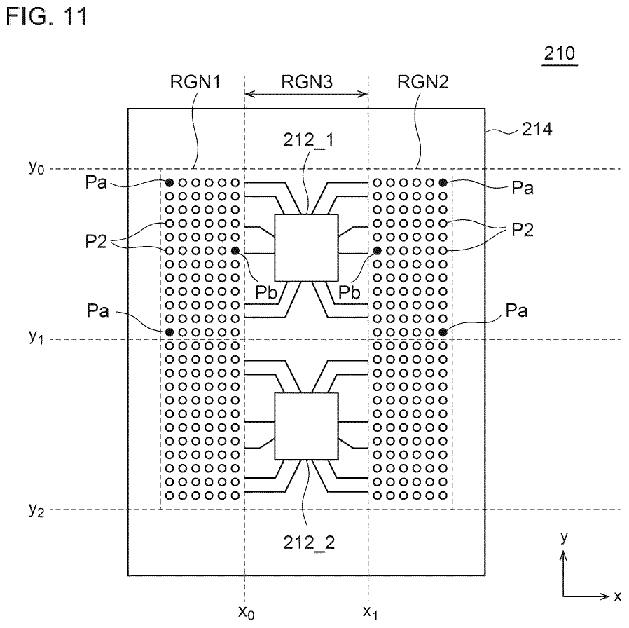

FIG. 10 is a perspective view illustrating the layout of a socket board 210 according to an embodiment. FIG. 11 is a plan view illustrating the layout of the socket board 210 according to the embodiment.

The socket board 210 includes a socket PCB 214 and N socket guides (simply referred to as “sockets”) 212_1 to 212_N. In this example, N equals 2.

The N sockets 212_1 to 212_N are provided on a first surface (upper surface in the figure) of the socket PCB 214.

On a second surface (lower surface in the figure) of the socket PCB 214, a plurality of pads P2 are formed, divided into a first region RGN1 and a second region RGN2. The plurality of pads P2 serve as electrical contact points with the interposer 218.

The first region RGN1 and the second region RGN2 are rectangular in shape, having the same shape and size, and are elongated along a first direction (y). These two regions are spaced apart from each other in a second direction (x).

Each of the N socket guides 212_1 to 212_N is disposed adjacent to each other in a y-direction, in a third region RGN3 that is interposed between the first region RGN1 and the second region RGN2 in an x-direction.

Each of the socket guides 212_1 to 212_N is electrically connected to a portion of the plurality of pads P2 included in the first region RGN1 and a portion of the plurality of pads P2 included in the second region RGN2. Each pin of the socket 212 and its corresponding pad P2 are electrically connected via wirings and via holes provided in the socket PCB 214.

One of the sockets 212_1 is disposed in the range of y₀ to y₁ in the y-direction, and the other socket 212_2 is disposed in the range of y₁ to y₂ in the y-direction. Here, y₀ is a coordinate at one end of the rectangular regions RGN1 and RGN2, y₂ is a coordinate at the other end, and y₁ is a coordinate at the center.

In the layout of FIG. 11, Pa represents the farthest pad among the pads connected to the socket 212_1, and Pb represents the nearest pad among the pads connected to the socket 212_1.

The foregoing describes the layout of the socket board 210. The advantages of this socket board 210 become apparent through comparison with comparative technology.

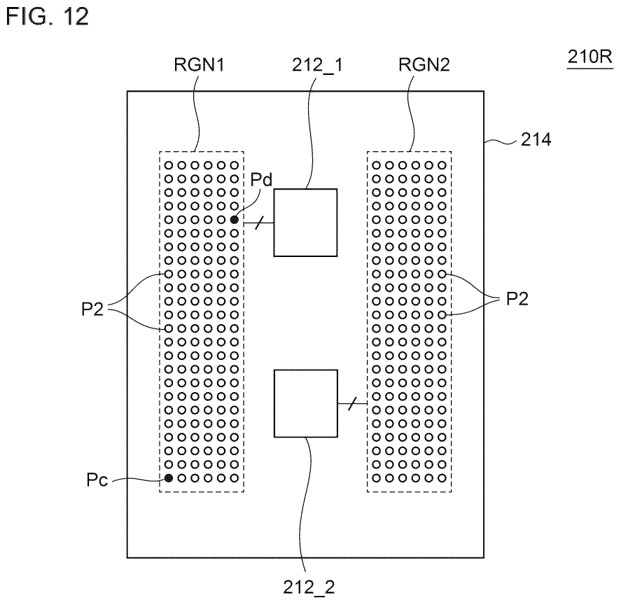

FIG. 12 is a plan view showing a layout of a socket board 210R according to comparative technology.

In this comparative technology, one of the sockets 212_1 is connected to the pads P2 included in the first region RNG1, and the other socket 212_2 is connected to the pads P2 included in the second region RNG2.

In the layout shown in FIG. 12, Pc represents the farthest pad among the pads connected to the socket 212_1, and Pd represents the closest pad among the pads connected to the socket 212_1.

By comparing FIG. 11 (embodiment) and FIG. 12 (comparative example), it can be understood that the wiring length from the socket to the farthest pad is shorter in FIG. 11 (embodiment). As a result, parasitic impedance is reduced, allowing for a wider bandwidth and enabling the testing of higher-speed signals.

Further, by comparing FIG. 11 (embodiment) and FIG. 12 (comparative example), it can be seen that the difference between the distance Pa to the farthest pad and the distance to the nearest pad Pb in FIG. 11 (embodiment) is smaller than the difference between the distance Pc to the farthest pad and the distance to the nearest pad Pd in FIG. 12 (comparative example). In other words, according to the embodiment, the wiring lengths to the plurality of pads P2 can be made more uniform compared to the comparative example.

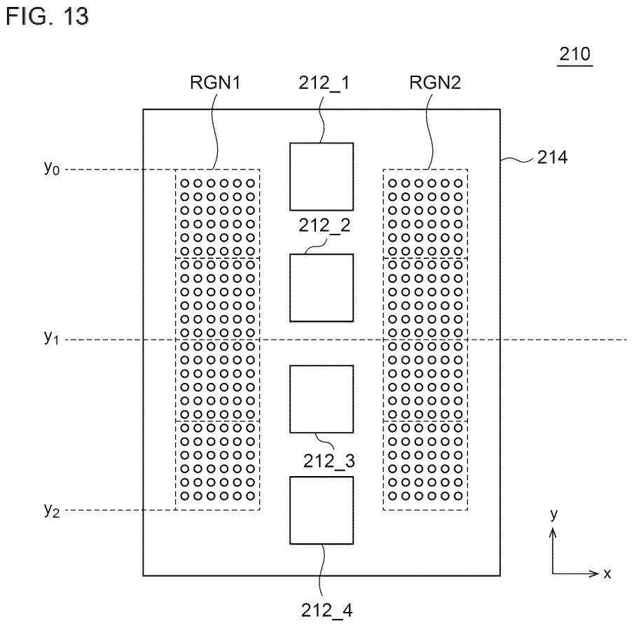

FIG. 13 is a plan view illustrating the layout of a socket board 210 according to a modified example. In this modified example, the number N of sockets 212 is four. In this layout, the two central sockets 212_2 and 212_3 are disposed such that, in the Y-direction, they fall within the range y₀ to y₂ of the rectangular regions RGN1 and RGN2. Accordingly, advantages similar to those of the layout shown in FIG. 10 can be achieved.

Subsequently, management of the socket board will be described.

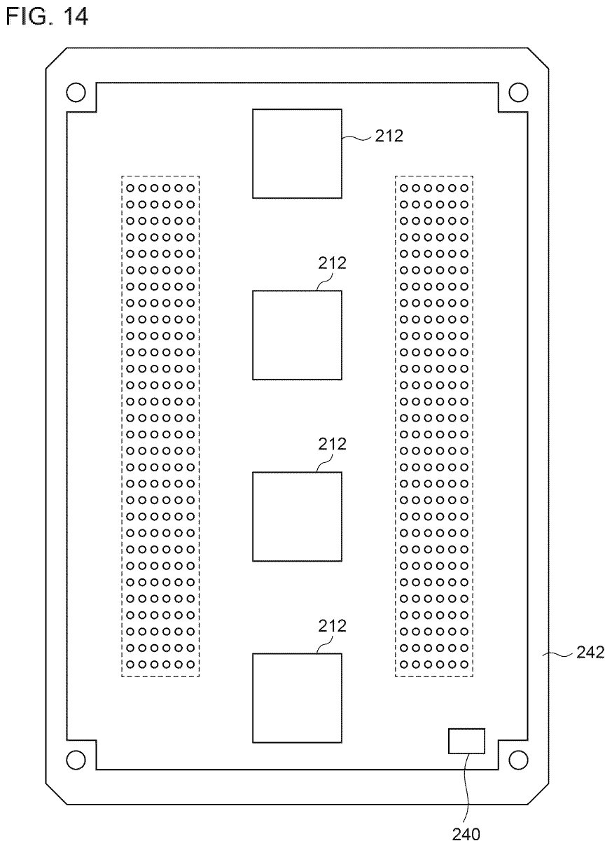

FIG. 14 illustrates a socket board 210A according to an embodiment. The socket board 210A includes a socket PCB 214, a socket 212, and a non-volatile memory 240. The non-volatile memory 240 is readable from the tester main unit. The non-volatile memory 240 is an Electrically Erasable Programmable Read-Only Memory (EEPROM) or a flash memory.

The non-volatile memory 240 can be disposed at a position along the outer periphery of the socket PCB 214, for example, at one of the four corners. A ground pattern 242 is formed along the outer periphery of the socket PCB 214, and the non-volatile memory 240 may be disposed adjacent to the ground pattern 242.

Generally, a plurality of socket boards (for example, sixteen boards) are mechanically connected by a component referred to as a socket frame, forming a single unit. This unit may also be referred to as a DSA (Device Specific Adapter) or a device board. Conventionally, a non-volatile memory has been provided for each DSA, and information specific to the DSA has been stored therein.

The present inventors have studied conventional DSAs and independently recognized the following issue. In conventional ATEs handling relatively low-speed signals, individual differences between socket boards could be ignored or were not a significant concern. However, in high-speed testing—specifically, in testing high-speed memory operating at speeds exceeding 20 Gbps—such individual differences in socket boards can no longer be disregarded.

Accordingly, in the present embodiment, a non-volatile memory 240 is provided for each socket board 210A, and the non-volatile memory 240 is capable of storing information unique to each socket board 210. For example, the non-volatile memory 240 can store the following types of information.

(i) Information regarding the socket 212 provided on the socket board 210A. Specific examples include the position of the socket board and the pin arrangement. The tester main unit reads this information from the socket board 210A and transmits it to the handler. This allows the handler to place the DUT in the correct position on the socket board 210A.

Mechanical components may undergo dimensional changes due to temperature variations or aging. The operator of the ATE 100 can compare the actual position at which the handler has placed the DUT—i.e., the actual position of the socket—with the socket position information stored in the nonvolatile memory 240. This enables the operator to observe how the actual position of the socket 212 shifts over time or due to temperature changes.

(ii) A serial number or management number of the socket board 210A.

(iii) Information related to the contact by the handler with the socket board, such as the number of contacts and the contact depth, which can be managed for each socket board.

The above describes the configuration of the socket board 210A. According to this socket board 210A, various types of information can be managed on a per-socket-board basis, rather than on a per-DSA basis. This makes it possible to conduct test operations that take into account variations between individual socket boards, thereby enabling accurate testing of high-speed memory devices operating at over 20 Gbps. Needless to say, the architecture of the present embodiment is also applicable to the testing of memory devices with bandwidths lower than 20 Gbps, as well as other DUTs.

Various types of interface devices 200 exist, and the present disclosure is applicable to any of these types.

### SBC (Socket Board Change) Type

The SBC type is an interface device in which the socket board 210 is replaced in accordance with the type of DUT.

### CLS (Cable Less) Type

The CLS type is an interface device in which the upper part (a device specific adapter, or DSA) and the lower part (a motherboard) of the interface device 200 are separable, and the DSA is replaced according to the type of DUT. When the interface device 200 according to the present embodiment is applied to the CLS type, two configurations are possible.

In one configuration, the front-end module 300 is disposed on the motherboard side. In this case, the front-end module 300 can be shared across different DUT tests, which is advantageous from a cost perspective.

In another configuration, the front-end module 300 is disposed on the DSA side. In this case, although the front-end module 300 must be provided for each DSA, which increases the overall cost of the apparatus, the front-end module 300 can be placed closer to the DUT, which is advantageous for high-speed testing.

### CCN (Cable Connection) Type

The CCN type is an interface device in which the entire interface device 200 is replaced according to the type of DUT. When the interface device 200 according to the present embodiment is applied to the CCN type, the front-end module 300 can be positioned extremely close to the DUT, which is advantageous for high-speed testing.

### Wafer Motherboard

The interface device 200 may be a wafer motherboard used for wafer-level testing. In this case, the interface device 200 may include a probe card in place of the socket board.

The above-described embodiments are illustrative, and it will be understood by those skilled in the art that various modifications can be made to the combinations of the individual components and processing steps. Several such modified examples will be described below.

### MODIFIED EXAMPLE 1

In the embodiment, the pin electronics ICs 400 are electrically connected to the FPC and the printed circuit board via an interposer. However, the present disclosure is not limited thereto. Instead of using an FPC cable 222 as the wiring 220, a printed circuit board or other types of wiring may be used.

### MODIFIED EXAMPLE 2

In the embodiment, the interface device 200 is described as having the socket board 210 arranged parallel to the ground. However, the present disclosure is not limited thereto. For example, the socket board 210 may be oriented vertically with respect to the ground. In that case, the Y direction in FIGS. 4 and 5 corresponds to the direction of gravity.

While the preferred embodiments of the present disclosure have been described using specific terms, such description is for illustrative purposes only, and it is to be understood that changes and variations may be made without departing from the spirit or scope of the appended claims.

What is claimed is:

1. A socket board comprising:
a socket printed circuit board;
a socket guide provided on the socket printed circuit board; and
a non-volatile memory provided on the socket printed circuit board and configured to store information related to the socket board.

2. The socket board according to claim 1, wherein the non-volatile memory is disposed along a peripheral edge of the socket printed circuit board.

3. The socket board according to claim 1, wherein the non-volatile memory is disposed at one of four corners of the socket printed circuit board.

4. Automatic test equipment comprising the socket board according to claim 1.
